(19) United States
(12) Patent Application Publication
(10) Pub. No.: US 2022/0319901 A1
(43) Pub. Date: Oct. 6, 2022

(54) DIRECT BONDING AND DEBONDING OF CARRIER

(71) Applicant: INVENSAS BONDING TECHNOLOGIES, INC., San Jose, CA (US)

(72) Inventors: Dominik Suwito, San Jose, CA (US); Gaius Gillman Fountain, JR., Youngsville, NC (US); Guilian Gao, San Jose, CA (US)

(21) Appl. No.: 17/708,688

(22) Filed: Mar. 30, 2022

Related U.S. Application Data
(60) Provisional application No. 63/168,946, filed on Mar. 31, 2021.

(51) Int. Cl. H01L 21/683; H01L 21/78

(52) U.S. Cl. CPC H01L 21/6835; H01L 21/78; H01L 2221/68327; H01L 2221/68381

(57) ABSTRACT

A bonding method is disclosed. The method can include directly bonding a first nonconductive bonding material of a semiconductor element to a second nonconductive bonding material of a carrier without an intervening adhesive. The first nonconductive bonding material is disposed on a device portion of the semiconductor element. The second nonconductive bonding material is disposed on a bulk portion of the carrier. A deposited dielectric layer is disposed between the device portion and the bulk portion. The method can include removing the carrier from the semiconductor element by transferring thermal energy to the dielectric layer to induce diffusion of gas out of the dielectric layer.

### CROSS-REFERENCE TO RELATED APPLICATIONS

This application claims priority to U.S. Provisional Patent Application No. 63/168,946, filed Mar. 31, 2021, titled “DIRECT BONDING AND DEBONDING OF CARRIER,” the entire contents of each of which are hereby incorporated herein by reference.

### BACKGROUND

### Field

The field relates to direct bonding of a semiconductor element to a carrier, and to removing the carrier after the direct bonding.

### Description of the Related Art

Semiconductor elements, such as semiconductor wafers, can be stacked and directly bonded to one another without an adhesive. For example, in some direct bonded structures, nonconductive field regions of the elements can be directly bonded to one another. In some structures, corresponding conductive contact structures can also be directly bonded to one another. In some applications, it can be challenging to form thinned dies and wafers, and/or to conduct backside processing. Accordingly, there remains a continuing need for improved methods and structures for direct bonding.

### BRIEF DESCRIPTION OF THE DRAWINGS

Specific implementations will now be described with reference to the following drawings, which are provided by way of example, and not limitation.

FIG. 1A is a schematic cross sectional side view of two elements prior to bonding.

FIG. 1B is a schematic cross sectional side view of the two elements shown in FIG. 1A after bonding.

FIGS. 2A-2E illustrate schematic cross sectionals views of various steps in a bonding method according to an embodiments.

FIG. 3 is a flow diagram showing a method of bonding and debonding a semiconductor device and a carrier.

### DETAILED DESCRIPTION

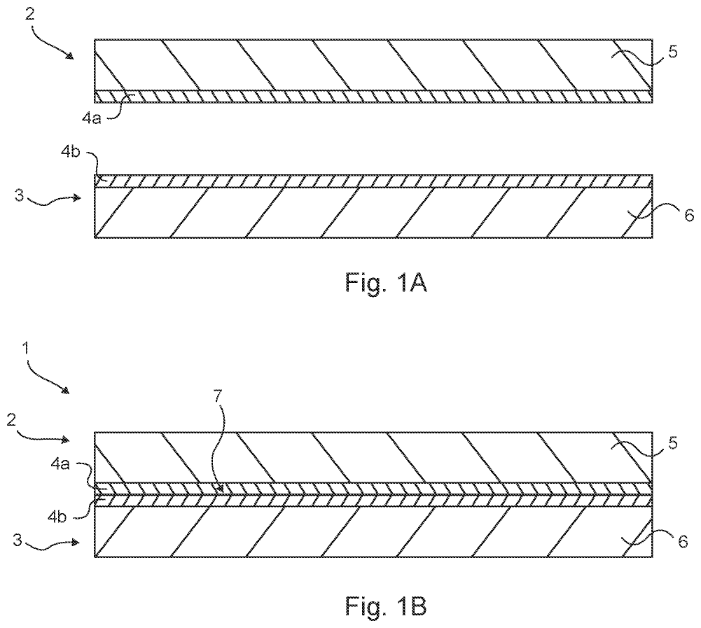

In various microelectronic devices, two or more elements 2, 3 can be directly bonded to one another without an adhesive to form a bonded structure. The elements 2, 3 of FIGS. 1A and 1B can comprise semiconductor elements in some embodiments. For example, in various embodiments, the first and second elements 2, 3 can comprise semiconductor wafers. In some embodiments, the first and second elements 2, 3 can comprise semiconductor device dies. In some embodiments, one of the first and second elements 2, 3 can comprise a semiconductor wafer, and the other of the first and second elements 2, 3 can comprise a semiconductor device die. In various embodiments disclosed herein, the second element 3 can comprise a carrier which can be temporarily direct bonded to the first element 2, and subsequently removed (e.g., after thinning and/or other processing). For example, in some embodiments, the first element 2 can comprise a semiconductor element (e.g., a singulated integrated device die or an unsingulated wafer) having a device portion 5 and a first non-conductive bonding material 4a on the device portion 5. The device portion 5 can comprise a semiconductor material with active circuitry formed therein. The second element 3 can comprise a substrate 6 and a second non-conductive bonding material 4b on the substrate 6. In some embodiments, the substrate 6 can comprise glass or a semiconductor (such as silicon).

In various embodiments, as shown in FIGS. 1A-1B, the non-conductive (e.g., semiconductor or inorganic dielectric) bonding material 4a of the first element 2 can be directly bonded to the corresponding non-conductive (e.g., semiconductor or inorganic dielectric) bonding material 4b or field region of the second element 3 without an adhesive. In some embodiments (not shown), a conductive region (e.g., a metal pad or contact structure) of the first element 2 can be directly bonded to a corresponding conductive region (e.g., a metal pad or contact structure) of the second element 3 without an adhesive. In some embodiments, the non-conductive material 4a of the first element 2 can be directly bonded to the corresponding non-conductive material 4b of the second element 3 using bonding techniques without an adhesive using the direct bonding techniques disclosed at least in U.S. Pat. Nos. 9,564,414; 9,391,143; and 10,434,749, the entire contents of each of which are incorporated by reference herein in their entirety and for all purposes. Additional examples of hybrid bonding may be found throughout U.S. Pat. No. 11,056,390, the entire contents of which are incorporated by reference herein in their entirety and for all purposes. In other applications, in a bonded structure 1, a non-conductive material of a first element 2 can be directly bonded to a conductive material of a second element 3, such that a conductive material of the first element 2 is intimately mated with a non-conductive material of the second element 3. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SICOH dielectrics, silicon carbonitride or diamond-like carbon or a material comprising of a diamond surface. Such carbon-containing ceramic materials can be considered inorganic, despite the inclusion of carbon.

In various embodiments, direct bonds can be formed without an intervening adhesive. For example, semiconductor or dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. For example, in some embodiments, the bonding surface(s) can be exposed to a nitrogen-containing plasma. Further, in some embodiments, the bonding surfaces can be exposed to fluorine. For example, there may be one or multiple fluorine peaks near layer and/or bonding interfaces, particularly dielectric bonding interfaces. Thus, in the directly bonded structures, the bonding interface between two non-conductive materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element (for example, in arrangements in which both elements have contact pads). For example, a direct hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. The bond structures described herein can also be useful for direct metal bonding without non-conductive region bonding, or for other bonding techniques.

In some embodiments, inorganic dielectric bonding surfaces can be prepared and directly bonded to one another without an intervening adhesive as explained above. In direct bonded structures that have contact pads, the conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The coefficient of thermal expansion (CTE) of the dielectric material can range between 0.1 ppm/° C. and 5 ppm/° C., for example, and the CTE of the conductive material can range from 6 ppm/° C. and 40 ppm/° C., or between 8 ppm/° C. and 30 ppm/° C. The differences in the CTE of the dielectric material and the CTE of the conductive material restrain the conductive material from expanding laterally at subsequent thermal treating operations thereby facilitating the conductive pads to contact. The nonconductive bonding regions can be directly bonded to one another without an adhesive at room temperature in some embodiments and, subsequently, the bonded structure can be annealed. Upon annealing, the contact pads can expand with respect to the nonconductive bonding regions and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bond interface (e.g., small or fine pitches for regular arrays). In various embodiments, the contact pads can comprise copper, although other metals may be suitable. In arrangements in which the first and second elements 2, 3 do not have contact pads at the bonding surface, then the nonconductive materials can be directly bonded at room temperature without a subsequent anneal to effectuate metal contact.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer). In some embodiments, multiple dies having different CTEs may be bonded on the same carrier. In some embodiments, the CTE of the substrate of the bonded die can be similar to the CTE of the substrate of the carrier. In other embodiments the CTE of the substrate of the bonded die may be different from the CTE of the substrate of the carrier. The difference in CTEs between bonded dies or between bonded dies and the carrier may range between 1 ppm/° C. and 70 ppm/° C. and less than 30 ppm/° C., for example, less than 12 ppm/° C.

As explained herein, the first and second elements can be directly bonded to one another without an adhesive, which is different from a deposition process. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak or oxygen rich layer can be formed at the bond interface. In some embodiments, the bond interface can comprise a nitrogen-terminated inorganic non-conductive material, such as nitrogen-terminated silicon, silicon oxide, silicon nitride, silicon oxynitride, silicon oxycarbonitride, or silicon carbonitride, with levels of nitrogen present at the bonding interface that are indicative of nitrogen termination of at least one of the elements prior to direct bonding. Other than nitrogen-containing dielectrics, the nitrogen content of the non-conductive material typically has a gradient peaking at or near the surface. In some embodiments, nitrogen and nitrogen related moieties may not be present at the bonding interface. As explained herein, the direct bond can comprise a covalent bond, which is stronger than van Der Waals bonds. The bonding layers can also comprise polished surfaces that are planarized to a high degree of smoothness.

In various embodiments in which the elements 2, 3 have metallic contact pads that are directly bonded, the metal-to-metal bonds between the contact pads can be joined such that metal grains (e.g., copper grains) grow into each other across the bond interface. In some embodiments, the copper can have grains oriented vertically along the 111 crystal plane for improved copper diffusion across the bond interface. In some embodiments, however, other copper crystal planes can be oriented vertically relative to the contact pad surface. The nonconductive bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in U.S. Pat. No. 11,195,748, which is incorporated by reference herein in its entirety and for all purposes.

In some applications, it may be desirable to utilize thinned semiconductor elements, for example, in multi-element device stacks, such as memory devices. For example, a semiconductor element (such as a semiconductor device wafer) can be temporarily bonded to a carrier (e.g., a glass or silicon carrier wafer) by way of an adhesive, such as a heat curable or UV curable adhesive (e.g., an organic adhesive). The backside of the semiconductor element can be thinned by, for example, grinding and/or chemical mechanical polishing (CMP). Moreover, additional backside processing may be performed on the backside of the semiconductor element with the semiconductor element adhered to the carrier. For example, metallization or back-end-of-line (BEOL) layers of films may be deposited or otherwise provided on the thinned semiconductor element.

However, the use of adhesives in temporary bonds can be challenging in a number of respects. For example, as the device wafer is thinned, the residual stress from the BEOL film may cause lateral growth of the die size because the organic adhesive may not provide a sufficient bond strength to constrain the lateral growth of the device wafer. Furthermore, the mechanical stability of the adhesive bond between the device wafer and the carrier wafer during the thinning process (e.g., a grinding process) may deteriorate or become unreliable due to the forces imparted during thinning. In some cases, the thinning process may also cause the thickness of the device wafer to vary significantly so as to exceed a desired total thickness variation (TTV). For example, the intervening temporary adhesive between the device wafer and the carrier wafer can have non-uniformities that can result in excessive thickness variation upon thinning. Moreover, the temporary adhesive bond may not have sufficient thermal and/or chemical stability when exposed to various processes. For example, the temporary adhesive may degrade when exposed to the chemicals used for wafer cleaning, electrochemical deposition (ECD), and/or CMP. The adhesive may alternatively or additionally decompose during deposition and/or etch processes (such as chemical vapor deposition (CVD), plasma-enhanced CVD, physical vapor deposition, etc.). In addition, when the carrier and adhesive are removed from the device wafer, the device wafer may include residue from the adhesive, which may cause the use of an extra cleaning step. Accordingly, there remains a continuing need for improved methods and structures for thinning a semiconductor element.

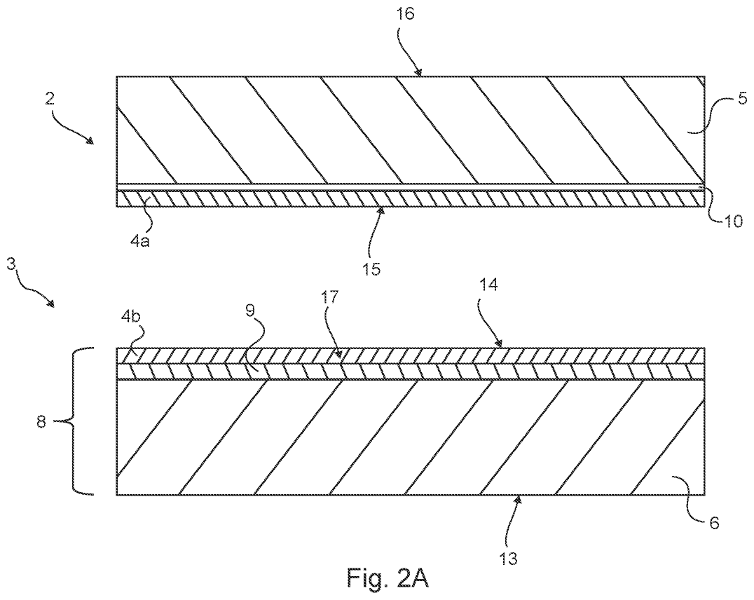

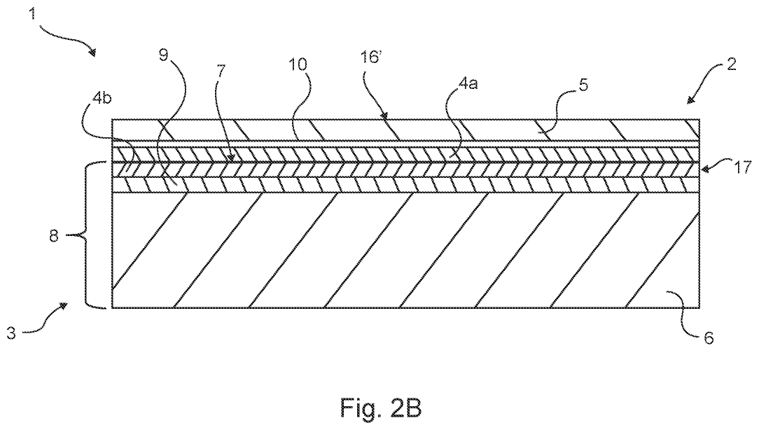

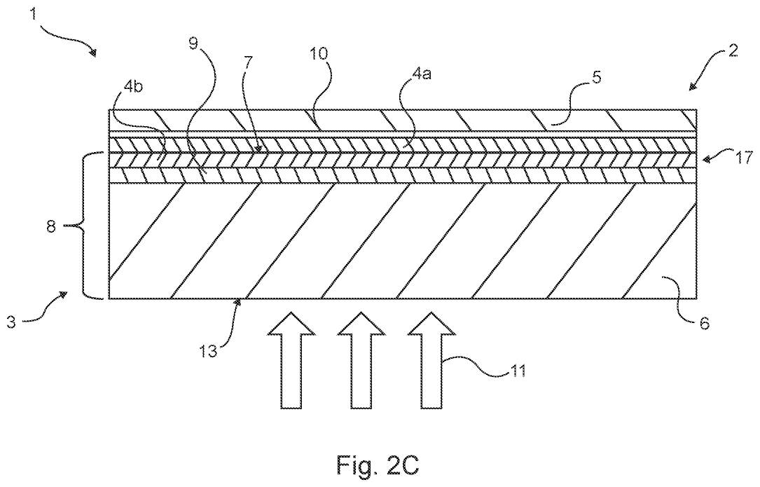

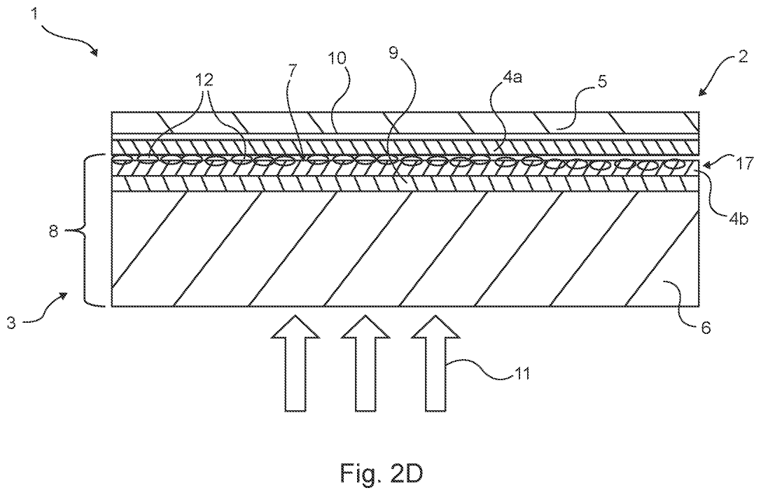

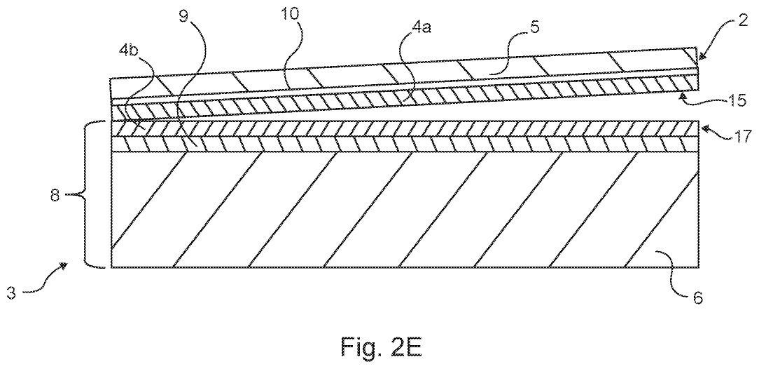

FIGS. 2A-2E illustrate an example bonding method, according to various embodiments. Unless otherwise noted, the components of FIGS. 2A-2E may be the same as or generally similar to like-numbered components of FIGS. 1A-1B. As shown in FIG. 2A, the first semiconductor element 2 can comprise a semiconductor device element in wafer form or as a singulated integrated device die. The semiconductor element 2 can comprise the device portion 5 having active circuitry and/or devices therein. In FIG. 2A, the semiconductor element 2 has a front side 15 and a back side 16 opposite the front side 15. The semiconductor element 2 and device portion 5 are shown in FIG. 2A prior to thinning, e.g., prior to grinding or polishing the back side 16 of the semiconductor element 2.

Further, a diffusion barrier layer 10 can be provided on the device portion 5. As explained herein, the diffusion barrier layer 10 can have a low gas permeability so as to reduce or prevent gases from diffusing into the device portion 5 and active circuitry therein. The diffusion barrier layer 10 can be configured to reduce or inhibit gases, such as hydrogen, from diffusing into the device portion 5 and active circuitry therein. In some embodiments, the diffusion barrier layer 10 can comprise a low gas permeability inorganic dielectric, such as silicon nitride. The diffusion barrier layer 10 can comprise a high density material that has a density more than 2.75 g/cc. In some embodiments, the diffusion barrier layer 10 can have a density in a range of 2.75 g/cc to 5 g/cc, 2.9 g/cc to 5 g/cc, 3 g/cc to 5 g/cc, 2.75 g/cc to 4 g/cc, 2.75 g/cc to 3.5 g/cc, or 3 g/cc to 3.5 g/cc. For example, the diffusion barrier layer 10 can have a density of about 3.17 g/cc. In some embodiments, the diffusion barrier layer 10 can have a density that is greater than a density of the device portion 5, a density of silicon, a density of silicon oxide, and/or a density of the first nonconductive bonding material 4a. For example, the barrier layer 10 can comprise a silicon base layer that is deposited by way of, for example, chemical vapor deposition CVD (e.g., plasma enhanced CVD (PECVD), or physical vapor deposition (PVD). The first nonconductive bonding material 4a can be provided on the diffusion barrier layer 10. In various embodiments, the first nonconductive bonding material 4a can comprise a dielectric bonding layer, such as silicon oxide, silicon oxynitride, silicon nitride, silicon oxynitrocarbide, etc. In some embodiments, the first nonconductive bonding material 4a can comprise a semiconductor material. In some embodiments, the first nonconductive bonding material 4a can comprise the diffusion barrier layer 10 such that the first nonconductive bonding material 4a itself serves as a diffusion barrier to outgassing. The diffusion barrier layer 10 can be blanket deposited across the device portion 5 of the first semiconductor element 2, e.g., across an entirety of a width of the device portion 5.

In FIG. 2A, the second element 3 can comprise a carrier 8. The carrier 8 can serve as a temporary support for the first semiconductor element 2 during various processing steps, such as thinning, backside metallization, and/or other processing. The carrier 8 can comprise a bulk carrier portion 6, which can comprise any suitable material such as glass, low-doped silicon, etc. An inorganic light-to-heat (LTH) conversion layer 9 can be provided on the bulk portion 6. For example, in some embodiments, the LTH conversion layer 9 can be bulk deposited on the bulk portion 6, e.g., across an entirety of a width of the bulk carrier portion 6. As explained herein, the LTH conversion layer 9 can be configured to convert light to thermal energy. In some embodiments, the LTH conversion layer 9 can comprise a metal. For example, the metal can comprise at least one of copper, aluminum, titanium, and titanium nitride. Other metals may be suitable. In other embodiments, the LTH conversion layer 9 can comprise microcrystalline silicon (μc-Si).

As shown in FIG. 2A, a dielectric layer 17 comprising the second nonconductive bonding material 4b can be provided on the LTH conversion layer 9. FIG. 2A illustrates the dielectric layer 17 deposited over the LTH conversion layer 9, such that the LTH conversion layer 9 is disposed between the bulk portion 6 of the carrier 8 and the dielectric layer 17. In other embodiments, as explained herein, there may be no LTH conversion layer 9. Rather, in such embodiments, the dielectric layer 17 can be provided on the bulk portion 6 (and/or over other buildup layers) without an intervening LTH conversion layer.

As shown in the embodiment of FIG. 2A, the carrier 8 can have a front surface 14 and a back surface 13 opposite the front surface 14. In the illustrated embodiment, the dielectric layer 17 (e.g., which can serve as the second nonconductive bonding layer 4b in some embodiments) can at least partially define the front surface 14. For example, in some embodiments, the dielectric layer 17 can be bulk deposited on the LTH conversion layer 9, e.g., across an entirety of a width of the LTH conversion layer 9. The dielectric layer 17 can comprise a porous dielectric material that is configured to allow outgassing of gases therefrom. Beneficially, the porosity and/or gas permeability of the dielectric layer 17 can be engineered during the deposition process. For example, to achieve a desired gas permeability, during the deposition process, one or more species of impurities can be introduced to increase gas permeability of the dielectric layer 17. In some embodiments, for example, the one or more species of impurities can comprise at least one of carbon and nitrogen in the dielectric layer 17. For example, in some embodiments, the dielectric layer 17 can comprise silicon oxynitrocarbide. Beneficially, therefore, various embodiments can provide for increased gas diffusion in the dielectric layer 17 using the deposition process, as opposed to other methods, such as ion implantation after deposition. For example, the dielectric layer 17 can comprise a porous dielectric material that has a high gas permeability to, e.g., hydrogen gas (H₂), argon, and/or water vapor. In some embodiments, the deposition of the dielectric layer 17 can be designed such that the hydrogen content in the dielectric layer 17 is at a desired level, so as to assist in selecting or deriving a hydrogen release temperature. The dielectric deposition can also be designed to have a sufficiently high quality dielectric for direct bonding so as to form a strong direct bond.

Turning to FIG. 2B, the front side 15 of the semiconductor element 2 and the front surface 14 of the carrier 8 can be prepared for direct bonding as explained herein. In some embodiments, the front side 15 and/or the front surface 14 can have a surface roughness of less than 15 Å rms, less than 10 Å rms, or less than 5 Å rms. The semiconductor element 2 and the carrier 8 can be brought together at room temperature. The prepared bonding surfaces can form a direct nonconductive bond along a bond interface 7. Beneficially, the direct bond interface 7 can provide a strong bond between the elements 2, 3 such that the bonding between the semiconductor element 2 and the carrier 8 is sufficiently strong to restrain lateral growth of the device wafer. After directly bonding the first element 2 to the carrier 8, the device portion 5 can be thinned to form a thinned back side 16′. The thinned first element 2 of FIG. 2B can have any suitable thickness. Backside processing for processing the back side 16′ of the semiconductor element 2 can be conducted to form one or more conductive features, and prepare the backside surface for direct bonding or solder interconnection. For example, when TSVs (not shown) are included in the element 2, dielectric layers can be deposited on the back side 16′. The TSVs can be revealed and the dielectric layer can be planarized to sub-nm roughness for direct bonding or processed with suitable material stacks over the TSVs for solder interconnect. Backside features such as redistribution layers, etched features and power distribution networks can be fabricated on the back side 16′ prior to debonding the element 3. Since the bonding surface(s) (the front side 15 and/or the front surface 14) has sub-nm roughness prior to bonding and the bonding interface has a thickness close to zero, a thickness variation during the backside processing can be minimized. The TTV in this case is predominantly affected by a grinding process, not by the temporary bonding process. For example, after thinning, the first element 2 can have a thickness of less than 100 microns, less than 50 microns, or less than 35 microns. For example, the thinned first element 2 can have a thickness in a range of 5 microns to 50 microns, 25 microns to 250 microns, in a range of 30 microns to 250 microns, in a range of 35 microns to 250 microns, or in a range of 35 microns to 100 microns.

After processing the first semiconductor element 2, the first semiconductor element 2 can be direct bonded to other semiconductor device element(s) (not shown) before removing the carrier 8. In this case, the carrier 8 can restrain lateral growth of the first semiconductor element 2 to enable precise alignment of the first semiconductor element 2 with the mating device element. The carrier 8 can provide mechanical support to prevent or mitigate potential damage of the thinned first semiconductor element 2 during preparation and bonding. This can be especially important for a die having a thickness of less than 50 um. The bonding process can lock the precisely aligned features in place. Any suitable number of semiconductor elements can be stacked and directly bonded to one another while supported by the carrier 8. The carrier 8 can then be removed. Removing the carrier 8 after aligning the first semiconductor element 2 with other device element(s) can prevent or mitigate misalignment of the already bonded devices.

Alternatively, after processing the first semiconductor element 2, the carrier 8 can be removed in a removal process. For example, after thinning and/or backside metallization (or other processes), the carrier 8 can be removed such that the semiconductor element 2 can undergo subsequent processes, including, e.g., bonding to other semiconductor device elements. Removing the carrier 8 at this point frees the thinned element 2 to expand laterally. For a large die with very fine bonding pitch applications, appropriate dimensional compensation may be provided to enable precise alignment of the element 2 to other semiconductor devices with varying thickness(es). For example, dimensional compensation techniques disclosed throughout U.S. Patent Application Publication No. 2021/0296282, filed Mar. 19, 2021, which is incorporated by reference herein in its entirety and for all purposes, may be used to improve alignment.

In FIG. 2C, the back surface 13 of the carrier 8 can be irradiated with light 11. The light 11 can comprise wavelength(s) to which the bulk portion 6 of the carrier 8 is transparent. The light can pass through the bulk portion 6 and can interact with the LTH conversion layer 9. The LTH conversion layer 9 can have a high absorption coefficient for the wavelength(s) of the light 11, such that the material of the layer 9 heats up when exposed to the light 11. In some embodiments, the LTH conversion layer 9 can be opaque or substantially opaque to the light 11 such that the light 11 does not pass through the layer 9 and impinge on metal in the first semiconductor element 2. In various embodiments, the light 11 can comprise infrared (IR) radiation. For example, the light 11 can have wavelength(s) in a range of 800 nm to 1400 nm, in a range of 800 nm to 1200 nm, or in a range of 800 nm to 1100 nm, e.g. about 1064 nm in one embodiment. Any suitable material having a high absorption coefficient at the wavelength(s) of the light 11 may be used. For example, the layer 9 can comprise silicon (e.g., microcrystal silicon) or a metal (such as copper, aluminum, titanium, or titanium nitride), that has a high absorption coefficient for IR wavelengths. The layer 9 may also have a good adhesion with the dielectric layer 17 so as to ensure separation at the bond interface 7 rather than at the interface between the dielectric layer 17 and the LTH layer 9. In various embodiments, titanium or titanium nitride may be used. In various embodiments, the light 11 can be irradiated on the carrier 8 using a laser, e.g., in a plurality of laser pulses.

Turning to FIG. 2D, the LTH layer 9 can absorb the light 11 that impinges on the carrier 8, and can convert the optical energy to thermal energy which can be transferred to the dielectric layer 17. The thermal energy can heat the dielectric layer 17 so as to increase its temperature, which can cause outgassing of trapped species or gases. Bubbles 12 of gas can form between the device portion 5 and the bulk portion 6. As explained herein, the outgassed bubbles 12 can comprise gas(es) dissolved in the dielectric layer 17, such as hydrogen gas, argon gas, residue gas precursor elements from the dielectric deposition process, and/or water vapor. The bubbles 12 can weaken a bond between the semiconductor element 2 and the carrier 8 to effectuate the removal of the carrier 8 from the semiconductor element 2. Thus, as shown in FIG. 2D, the laser pulse of light 11 can cause the local absorption of light, which can be converted to heat to cause outgassing by way of the bubbles 12. The bubbles 12 in the dielectric layer 17 can form a region of weakness at, in or near the dielectric layer 17, which can cause the carrier 8 (e.g., the bulk portion 6) to delaminate and separate from the first element 2. The diffusion barrier layer 10 can prevent or block the bubbles 12 of gas from diffusing into the device region 5 and interacting with active circuitry.

In FIG. 2E, the laser can be scanned across a width of the carrier 8, e.g., across the wafer or die. Scanning the light 11 across the carrier 8 can create sufficient voids across the width (e.g., across the entire bond interface 7) such that the carrier 8 is delaminated from the first element 2. As shown in FIG. 2E, for example, the delamination can occur along the bond interface 7 in some embodiments, such that the carrier 8 (including the dielectric layer 17, the LTH conversion layer 9, and the bulk portion 6) are removed from the first semiconductor element 2. In some embodiments, after the removal, the front side 15 of the first element 2 can be processed to remove any remaining residue from the carrier 8 and/or to prepare the first nonconductive bonding material 4a for subsequent direct bonding, e.g., to another semiconductor element (not shown). For example, the front side 15 can be etched and/or planarized after removal of the carrier (e.g., using a post-removal CMP process). In some embodiments, after the carrier 8 is removed, the first element 2 (which can be in wafer form) can be singulated into a plurality of device dies. In other embodiments, the first element 2 and the carrier 8 can be singulated before the carrier 8 is removed.

After the first element 2 has been separated from the carrier 8, the thinned and processed first element 2 can be directly bonded to other semiconductor elements to form a microelectronic device. In some embodiments, the first semiconductor element 2 can have a signature indicative of the carrier removal process. For example, in some arrangements, the nonconductive bonding material 4a of the first element 2 can include diffused gas. As explained above, the diffusion barrier layer 10 can block the gas from diffusing into the device region 5 and negatively affecting the active circuitry, but the nonconductive bonding material 4a may still include remnants or traces of the diffused gas. In some embodiments, the nonconductive bonding material 4a can include a higher content of certain gas(es) (the diffused gas) than the device region 5. In various embodiments, the diffused gas can comprise at least one of hydrogen gas (H2), argon, and water vapor. In some embodiments, however, a subsequent anneal (for example, when bonding opposing contact pads), may lead to further outgassing or out-diffusion of the species.

It should be appreciated that, in various embodiments, the dielectric layer 17 can be provided in other locations of the bonded structure 1. For example, although the dielectric layer 17 serves as the bonding layer 4b in the carrier 8 in the embodiment of FIGS. 2A-2E, in other embodiments, the dielectric layer 17 may be disposed below the bonding layer 4b. In still other embodiments, the dielectric layer 17 may be disposed on the first semiconductor element 2, e.g., the dielectric layer may serve as the first bonding material 4a or may comprise a dielectric layer between the first bonding material 4a and the diffusion barrier layer 10. Skilled artisans will appreciate that other configurations may be suitable to position the dielectric layer 17 between the device portion 5 of the first semiconductor element 2 and the bulk portion 6 of the carrier 8.

As explained above, in the embodiment illustrated in FIGS. 2A-2E, the LTH conversion layer 9 can be provided in the second element 3 to convert light to heat, which creates the bubbles that effectuates removal of the carrier 8 from the first element 2. However, as explained above in connection with FIG. 2A, in other embodiments, there may not be an intervening LTH conversion layer. Rather, as explained above, the dielectric layer 17 can be provided on the bulk portion 6 (and/or over other buildup layers) without an intervening LTH conversion layer. In such embodiments, the bonded structure 1 can be heated, e.g., placed in an oven, so as to raise the temperature above room temperature by a sufficient amount so as to create the gas bubbles 12. The transferred thermal energy from the heating can cause bubbles to form between the device portion 5 and the bulk portion 6. The bubbles 12 can weaken a bond between the semiconductor element 2 and the carrier 8 to effectuate the removal of the carrier 8 from the semiconductor element 2.

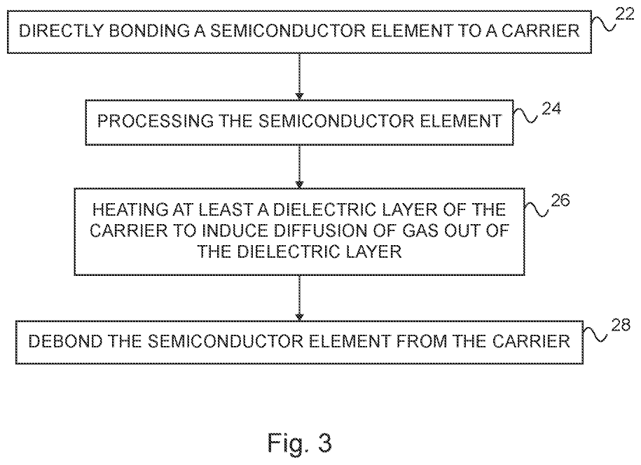

FIG. 3 is a flow diagram showing a method of bonding and debonding a semiconductor device and a carrier. At step 22, the semiconductor device and the carrier can be directly bonded to one another. At step 24, the semiconductor element can be processed. After thinning, backside processing can be conducted to add features and prepare the backside surface for direction bonding or solder interconnection. For example, when TSVs are included in the semiconductor element 2, dielectric layers can be deposited on the backside of the semiconductor element 2. The TSVs can be revealed and planarized to sub-nm roughness for direct bonding or prepared with suitable material stacks for solder interconnect. Backside features such as distribution layers, etched features and power distribution networks can be fabricated on the backside prior to debonding the element 3. At step 26, at least a dielectric layer of the carrier can be heated to induce diffusion of gas out of the dielectric layer. For example, light can be impinged on a light to heat (LTH) conversion layer through a transparent carrier of the carrier to cause thermal energy thereby heating the dielectric layer to induce outgassing and diffusion of the gas. At step 28, the semiconductor element can be removed from the carrier.

In one embodiment, a bonding method is disclosed. The bonding method can include directly bonding a first nonconductive bonding material of a semiconductor element to a second nonconductive bonding material of a carrier without an intervening adhesive, the first nonconductive bonding material disposed on a device portion of the semiconductor element, the second nonconductive bonding material disposed on a bulk portion of the carrier, wherein a deposited dielectric layer is disposed between the device portion and the bulk portion; and removing the carrier from the semiconductor element by transferring thermal energy to the dielectric layer to induce diffusion of gas out of the dielectric layer.

In some embodiments, the deposited dielectric layer comprises a porous dielectric material. In some embodiments, the second nonconductive bonding material of the carrier comprises the dielectric layer. In some embodiments, transferring thermal energy comprises heating the directly bonded carrier and semiconductor element. In some embodiments, the heating causes bubbles to form between the device portion and the bulk portion, the bubbles weakening a bond between the semiconductor element and the carrier to effectuate the removal of the carrier from the semiconductor element. In some embodiments, an inorganic light-to-heat (LTH) conversion layer is disposed between the bulk portion of the carrier and the dielectric layer, the LTH conversion layer configured to convert light to the thermal energy, and wherein transferring thermal energy comprises irradiating the LTH conversion layer with light. In some embodiments, the irradiating the LTH conversion layer heats the dielectric layer so as to cause bubbles to form between the device portion and the bulk portion, the bubbles weakening a bond between the semiconductor element and the carrier to effectuate the removal of the carrier from the semiconductor element. In some embodiments, irradiating the LTH conversion layer with light comprises irradiating the LTH conversion layer with infrared (IR) radiation. In some embodiments, irradiating the LTH conversion layer with light comprises irradiating the LTH conversion layer with a laser. In some embodiments, irradiating the LTH conversion layer with the laser comprises scanning the laser across a width of the carrier. In some embodiments, the carrier has a front surface and a back surface opposite the front surface, the second nonconductive bonding material at least partially defining the front surface, wherein irradiating the LTH conversion layer with light comprises irradiating the back surface of the carrier with the light. In some embodiments, the LTH conversion layer comprises a metal. In some embodiments, the metal comprises at least one of copper, aluminum, titanium, and titanium nitride. In some embodiments, the LTH conversion layer comprises microcrystalline silicon (μc-Si). In some embodiments, the method can include depositing the dielectric layer over the bulk portion of the carrier. In some embodiments, the method can include depositing a light-to-heat (LTH) conversion layer on the bulk portion of the carrier and depositing the dielectric layer on the LTH conversion layer. In some embodiments, depositing the dielectric layer comprises blanket depositing the dielectric layer across an entirety of the LTH conversion layer, and wherein depositing the LTH conversion layer comprises blanket depositing the LTH conversion layer across an entirety of the bulk portion. In some embodiments, the method can include, during the depositing, providing one or more species of impurities to increase gas permeability of the dielectric layer. In some embodiments, providing the one or more species of impurities comprises providing at least one of carbon and nitrogen in the dielectric layer. In some embodiments, the dielectric layer comprises silicon oxynitrocarbide. In some embodiments, the method can include inducing diffusion of at least one of hydrogen gas (H2), argon, and water vapor from the dielectric layer. In some embodiments, the directly bonding is performed at room temperature. In some embodiments, the method can include, before the directly bonding, activating at least one of the first and second nonconductive bonding materials. In some embodiments, activating comprises exposing at least one of the first and second nonconductive bonding materials to a nitrogen-containing plasma. In some embodiments, a diffusion barrier layer is disposed between the dielectric layer and circuitry in the device portion of the semiconductor element, the diffusion barrier layer having a lower permeability to the gas than the deposited layer. In some embodiments, the diffusion barrier layer comprises silicon nitride. In some embodiments, the method can include, after the directly bonding, thinning a back side of the semiconductor element, the back side opposite the nonconductive bonding material. In some embodiments, the method can include directly bonding a second semiconductor element to the semiconductor element. In some embodiments, the removing is performed after directly bonding the second semiconductor element to the semiconductor element. In some embodiments, the method can include, after the removing, singulating the semiconductor element into a plurality of singulated semiconductor elements. In some embodiments, the method can include, before the removing, singulating the carrier and the semiconductor element into a plurality of bonded structures.

In another embodiment, a carrier can include: a bulk portion; a light-to-heat (LTH) conversion layer on the bulk portion of the carrier, the LTH conversion layer configured to convert light to thermal energy; and a dielectric layer on the LTH conversion layer, the dielectric layer comprising a deposited layer, the deposited layer sufficiently permeable to permit diffusion of gas out of the dielectric layer when heated.

In some embodiments, the dielectric layer comprises a porous inorganic dielectric material. In some embodiments, the LTH conversion layer is blanket deposited on the bulk portion and the dielectric layer is blanket deposited on the LTH conversion layer. In some embodiments, the bulk portion comprises at least one of glass and lowly doped silicon. In some embodiments, the LTH conversion layer comprises a metal. In some embodiments, the metal comprises at least one of copper, aluminum, titanium, and titanium nitride. In some embodiments, the LTH conversion layer comprises microcrystalline silicon (μc-Si). In some embodiments, the dielectric layer comprises silicon oxynitrocarbide. In some embodiments, the dielectric layer includes impurities added during deposition of the dielectric layer. In some embodiments, the impurities comprise at least one of carbon and nitrogen. In some embodiments, a bonded structure can include a semiconductor element directly bonded to the carrier without an intervening adhesive, a nonconductive bonding material of the semiconductor element directly bonded to the dielectric layer. In some embodiments, a diffusion barrier layer can be disposed in or on the semiconductor element between the dielectric layer and circuitry in a device portion of the semiconductor element, the diffusion barrier layer having a lower permeability to the gas than the deposited layer. In some embodiments, the diffusion barrier layer comprises silicon nitride. In some embodiments, the diffusion barrier layer is disposed between the nonconductive bonding material and the circuitry. In some embodiments, the nonconductive bonding material comprises a dielectric bonding layer.

In another embodiment, a semiconductor element can include: a device portion including circuitry; a diffusion barrier layer blanket deposited over the device portion, the diffusion barrier layer having a sufficiently low permeability to inhibit diffusion of gases to the device portion; and a nonconductive bonding material over the diffusion barrier layer such that the diffusion barrier layer is between the nonconductive bonding material and the device portion, the nonconductive bonding material having a planarized bonding surface prepared for direct bonding to a second semiconductor element.

In some embodiments, the diffusion barrier layer comprises silicon nitride. In some embodiments, the nonconductive bonding material comprises a dielectric bonding layer. In some embodiments, the nonconductive bonding material includes diffused gas therein. In some embodiments, the diffused gas comprises at least one of hydrogen gas (H2), argon, and water vapor. In some embodiments, a bonded structure can include a second semiconductor element directly bonded to the semiconductor element without an intervening adhesive.

In one aspect, a bonding method is disclosed. The bonding method can include directly bonding a first nonconductive bonding material of a semiconductor element to a second nonconductive bonding material of a carrier without an intervening adhesive. The first nonconductive bonding material is disposed on a device portion of the semiconductor element. The second nonconductive bonding material is disposed on a bulk portion of the carrier. A deposited dielectric layer is disposed between the device portion and the bulk portion. The bonding method can include removing the carrier from the semiconductor element by transferring thermal energy to the dielectric layer to induce diffusion of gas out of the dielectric layer.

In one embodiment, the deposited dielectric layer comprises a porous dielectric material.

In one embodiment, the second nonconductive bonding material of the carrier comprises the dielectric layer.

In one embodiment, transferring thermal energy comprises heating the directly bonded carrier and semiconductor element. The heating can cause bubbles to form between the device portion and the bulk portion. The bubbles can weaken a bond between the semiconductor element and the carrier to effectuate the removal of the carrier from the semiconductor element.

In one embodiment, an inorganic light-to-heat (LTH) conversion layer is disposed between the bulk portion of the carrier and the dielectric layer. The LTH conversion layer can be configured to convert light to the thermal energy. Transferring thermal energy can include comprise irradiating the LTH conversion layer with light. The irradiating the LTH conversion layer can heat the dielectric layer so as to cause bubbles to form between the device portion and the bulk portion. The bubbles can weaken a bond between the semiconductor element and the carrier to effectuate the removal of the carrier from the semiconductor element. Irradiating the LTH conversion layer with light can include irradiating the LTH conversion layer with infrared (IR) radiation. Irradiating the LTH conversion layer with light can include irradiating the LTH conversion layer with a laser. Irradiating the LTH conversion layer with the laser can include scanning the laser across a width of the carrier. The carrier can has a front surface and a back surface opposite the front surface. The second nonconductive bonding material can at least partially define the front surface. Irradiating the LTH conversion layer with light can include irradiating the back surface of the carrier with the light. The LTH conversion layer can include a metal. The metal includes at least one of copper, aluminum, titanium, and titanium nitride. The LTH conversion layer can include microcrystalline silicon (μc-Si).

In one embodiment, the bonding method further includes depositing the dielectric layer over the bulk portion of the carrier.

In one embodiment, the bonding method further includes depositing a light-to-heat (LTH) conversion layer on the bulk portion of the carrier and depositing the dielectric layer on the LTH conversion layer. Depositing the dielectric layer can include blanket depositing the dielectric layer across an entirety of the LTH conversion layer. Depositing the LTH conversion layer can include blanket depositing the LTH conversion layer across an entirety of the bulk portion.

In one embodiment, the bonding method further includes, during the depositing, providing one or more species of impurities to increase gas permeability of the dielectric layer. Providing the one or more species of impurities can include providing at least one of carbon and nitrogen in the dielectric layer. The dielectric layer can include silicon oxynitrocarbide.

In one embodiment, the bonding method further includes diffusion of at least one of hydrogen gas (H₂), argon, and water vapor from the dielectric layer.

In one embodiment, the directly bonding is performed at room temperature.

In one embodiment, the bonding method further includes, before the directly bonding, activating at least one of the first and second nonconductive bonding materials. Activating can include exposing at least one of the first and second nonconductive bonding materials to a nitrogen-containing plasma.

In one embodiment, a diffusion barrier layer is disposed between the dielectric layer and circuitry in the device portion of the semiconductor element. The diffusion barrier layer can have a lower permeability to the gas than the deposited layer. The diffusion barrier layer can include silicon nitride.

In one embodiment, the bonding method further includes, after the directly bonding, thinning a back side of the semiconductor element, the back side opposite the nonconductive bonding material. The bonding method can further include, after the direct bonding, forming a conductive structure at or near the back side of the semiconductor element. The bonding method can further include directly bonding a second semiconductor element to the backside of the semiconductor element. The the removing is performed after directly bonding the second semiconductor element to the semiconductor element.

In one embodiment, the bonding method further includes, after the removing, singulating the semiconductor element into a plurality of singulated semiconductor elements.

In one embodiment, the bonding method further includes, before the removing, singulating the carrier and the semiconductor element into a plurality of bonded structures.

In one aspect, a carrier is disclosed. The carrier can include a bulk portion, a light-to-heat (LTH) conversion layer on the bulk portion of the carrier, and a dielectric layer on the LTH conversion layer. The LTH conversion layer is configured to convert light to thermal energy. The dielectric layer includes a deposited layer. The deposited layer sufficiently permeable to permit diffusion of gas out of the dielectric layer when heated.

In one embodiment, the dielectric layer includes a porous inorganic dielectric material.

In one embodiment, the LTH conversion layer is blanket deposited on the bulk portion and the dielectric layer is blanket deposited on the LTH conversion layer.

In one embodiment, the bulk portion includes at least one of glass and lowly doped silicon.

In one embodiment, the LTH conversion layer includes a metal.

In one embodiment, the metal includes at least one of copper, aluminum, titanium, and titanium nitride.

In one embodiment, the LTH conversion layer includes microcrystalline silicon (μc-Si).

In one embodiment, the dielectric layer includes silicon oxynitrocarbide.

In one embodiment, the dielectric layer includes impurities added during deposition of the dielectric layer. The impurities comprise at least one of carbon and nitrogen.

In one embodiment, a bonded structure includes a semiconductor element directly bonded to the carrier without an intervening adhesive. A nonconductive bonding material of the semiconductor element is directly bonded to the dielectric layer. The bonded structure can further include a diffusion barrier layer disposed in or on the semiconductor element between the dielectric layer and circuitry in a device portion of the semiconductor element. The diffusion barrier layer can have a lower permeability to the gas than the deposited layer. The diffusion barrier layer can include silicon nitride. The diffusion barrier layer can be disposed between the nonconductive bonding material and the circuitry. The nonconductive bonding material includes a dielectric bonding layer.

In one aspect, a semiconductor element is disclosed. the semiconductor element can include a device portion including circuitry, a diffusion barrier layer blanket deposited over the device portion, and a nonconductive bonding material over the diffusion barrier layer such that the diffusion barrier layer is between the nonconductive bonding material and the device portion. The diffusion barrier layer is configured to reduce or inhibit diffusion of gases into the device portion. The nonconductive bonding material has a planarized bonding surface prepared for direct bonding to a second semiconductor element.

In one embodiment, the diffusion barrier layer includes a hydrogen barrier layer. The diffusion barrier layer can have a density in a range from 2.75 g/cc to 5 g/cc. The diffusion barrier layer can have a density greater than a density of the nonconductive boding material. The diffusion barrier layer can have a density greater than a density of the device portion.

In one embodiment, the nonconductive bonding material comprises a dielectric bonding layer.

In one embodiment, the nonconductive bonding material includes diffused gas therein. The diffused gas can include at least one of hydrogen gas (H₂), argon, and water vapor.

In one embodiment, a bonded structure includes a second semiconductor element directly bonded to the semiconductor element without an intervening adhesive.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bonding method comprising:
directly bonding a first nonconductive bonding material of a semiconductor element to a second nonconductive bonding material of a carrier without an intervening adhesive, the first nonconductive bonding material disposed on a device portion of the semiconductor element, the second nonconductive bonding material disposed on a bulk portion of the carrier, wherein a deposited dielectric layer is disposed between the device portion and the bulk portion; and
removing the carrier from the semiconductor element by transferring thermal energy to the dielectric layer to induce diffusion of gas out of the dielectric layer.

2. The bonding method of claim 1, wherein the deposited dielectric layer comprises a porous dielectric material.

3. The bonding method of claim 1, wherein the second nonconductive bonding material of the carrier comprises the dielectric layer.

4. The bonding method of claim 1, wherein transferring thermal energy comprises heating the directly bonded carrier and semiconductor element, the heating causes bubbles to form between the device portion and the bulk portion, the bubbles weakening a bond between the semiconductor element and the carrier to effectuate the removal of the carrier from the semiconductor element.

5. (canceled)

6. The bonding method of claim 1, wherein an inorganic light-to-heat (LTH) conversion layer is disposed between the bulk portion of the carrier and the dielectric layer, the LTH conversion layer configured to convert light to the thermal energy, and wherein transferring thermal energy comprises irradiating the LTH conversion layer with light.

7. The bonding method of claim 6, wherein the irradiating the LTH conversion layer heats the dielectric layer so as to cause bubbles to form between the device portion and the bulk portion, the bubbles weakening a bond between the semiconductor element and the carrier to effectuate the removal of the carrier from the semiconductor element.

8. The bonding method of claim 6, wherein irradiating the LTH conversion layer with light comprises irradiating the LTH conversion layer with infrared (IR) radiation.

9. The bonding method of claim 6, wherein irradiating the LTH conversion layer with light comprises irradiating the LTH conversion layer with a laser.

10. The bonding method of claim 9, wherein irradiating the LTH conversion layer with the laser comprises scanning the laser across a width of the carrier.

11. The bonding method of claim 6, wherein the carrier has a front surface and a back surface opposite the front surface, the second nonconductive bonding material at least partially defining the front surface, wherein irradiating the LTH conversion layer with light comprises irradiating the back surface of the carrier with the light.

12. The bonding method of claim 6, wherein the LTH conversion layer comprises a metal, the metal comprises at least one of copper, aluminum, titanium, and titanium nitride.

13. (canceled)

14. The bonding method of claim 6, wherein the LTH conversion layer comprises microcrystalline silicon (μc-Si).

15. The bonding method of claim 1, further comprising depositing the dielectric layer over the bulk portion of the carrier.

16. The bonding method of claim 15, further comprising depositing a light-to-heat (LTH) conversion layer on the bulk portion of the carrier and depositing the dielectric layer on the LTH conversion layer, wherein depositing the dielectric layer comprises blanket depositing the dielectric layer across an entirety of the LTH conversion layer, and wherein depositing the LTH conversion layer comprises blanket depositing the LTH conversion layer across an entirety of the bulk portion.

17. (canceled)

18. The bonding method of claim 15, further comprising, during the depositing, providing one or more species of impurities to increase gas permeability of the dielectric layer.

19. The bonding method of claim 17, wherein providing the one or more species of impurities comprises providing at least one of carbon and nitrogen in the dielectric layer.

20. The bonding method of claim 15, wherein the dielectric layer comprises silicon oxynitrocarbide.

21. The bonding method of claim 1, further comprising inducing diffusion of at least one of hydrogen gas (H₂), argon, and water vapor from the dielectric layer.

22. The bonding method of claim 1, wherein the directly bonding is performed at room temperature.

23. The bonding method of claim 1, further comprising, before the directly bonding, activating at least one of the first and second nonconductive bonding materials, wherein activating comprises exposing at least one of the first and second nonconductive bonding materials to a nitrogen-containing plasma.

24. (canceled)

25. The bonding method of claim 1, wherein a diffusion barrier layer is disposed between the dielectric layer and circuitry in the device portion of the semiconductor element, the diffusion barrier layer having a lower permeability to the gas than the deposited layer, the diffusion barrier layer comprises silicon nitride.

26. (canceled)

27. The bonding method of claim 1, further comprising, after the directly bonding, thinning a back side of the semiconductor element, the back side opposite the nonconductive bonding material, and forming a conductive structure at or near the back side of the semiconductor element.

28. (canceled)

29. The bonding method of claim 27, further comprising directly bonding a second semiconductor element to the backside of the semiconductor element, wherein the removing is performed after directly bonding the second semiconductor element to the semiconductor element.

30. (canceled)

31. The bonding method of claim 1, further comprising, after the removing, singulating the semiconductor element into a plurality of singulated semiconductor elements.

32. The bonding method of claim 1, further comprising, before the removing, singulating the carrier and the semiconductor element into a plurality of bonded structures.

33-56. (canceled)
